(19) United States
(12) Patent Application Publication
(10) Pub. No.: US 2024/0414949 A1
(43) Pub. Date: Dec. 12, 2024

(54) DISPLAY PANEL, METHOD FOR MANUFACTURING THE DISPLAY PANEL, AND ELECTRONIC APPARATUS INCLUDING THE DISPLAY PANEL

(71) Applicant: Samsung Display Co., LTD., Yongin-si (KR)

(72) Inventors: HYUNEOK SHIN, Yongin-si (KR); JUHYUN LEE, Yongin-si (KR); SUNGJOO KWON, Yongin-si (KR)

(21) Appl. No.: 18/606,594

(22) Filed: Mar. 15, 2024

(30) Foreign Application Priority Data
Jun. 7, 2023 (KR) 10-2023-0072671

(51) Int. Cl. H10K 59/122; G02B 27/01; H10K 59/12; H10K 59/80; H10K 71/60; H10K 102/00; H10K 102/10

(52) U.S. Cl. CPC H10K 59/122; G02B 27/0172; H10K 59/1201; H10K 59/80517; H10K 71/60; H10K 2102/103; H10K 2102/351

(57) ABSTRACT

A display panel includes a light-emitting element and a pixel defining film having a pixel opening defined therein. The light-emitting element may include a first electrode exposed through the pixel opening, a second electrode disposed on the first electrode, and at least one functional layer disposed between the first electrode and the second electrode. The first electrode may include a first layer including an aluminum alloy, a second layer including a transparent conductive oxide, and an anti-oxidation layer including titanium nitride (TiN) and disposed between the first layer and the second layer. When the atomic percentage is about 100 at %, the percentage of alloy atoms excluding aluminum atoms in the aluminum alloy may be about 0.01 at % to about 0.1 at %.

This application claims priority to Korean Patent Application No. 10-2023-0072671, filed on Jun. 7, 2023, and all the benefits accruing therefrom under 35 U.S.C. § 119, the content of which in its entirety is herein incorporated by reference.

### BACKGROUND

### 1. Field

The present invention relates to a display panel including a light-emitting element, a method for manufacturing the display panel, and an electronic apparatus including the display panel.

### 2. Description of the Related Art

Various types of electronic apparatuses that can be worn on a human body are being developed, and these apparatuses are generally referred to as a wearable electronic apparatus. The wearable electronic apparatus may have various forms that can be detachably attached to a part of the human body or clothes. As an example of the wearable electronic apparatus, there is a device that can be mounted on a user's head, and such a device may be referred to as, for example, a head-mounted display (HMD) device. A device such as an HMD device requires formation of a microstructure with an ultra-high resolution of about 3000 ppi (pixels per inch) or more.

### SUMMARY

The present disclosure provides a display panel with excellent display quality and an electronic apparatus including the display panel.

The present disclosure also provides a method for manufacturing a display panel with excellent manufacturing efficiency and manufacturing reliability.

An embodiment provides a display panel including a light-emitting element and a pixel defining film having a pixel opening defined therein, wherein the light-emitting element includes a first electrode exposed through the pixel opening, a second electrode disposed on the first electrode and at least one functional layer disposed between the first electrode and the second electrode, wherein the first electrode includes a first layer including an aluminum alloy, a second layer including a transparent conductive oxide and an anti-oxidation layer including titanium nitride (TiN) and disposed between the first layer and the second layer, wherein, when the atomic percentage is about 100 at %, the percentage of alloy atoms excluding aluminum atoms in the aluminum alloy is about 0.01 at % to about 0.1 at %.

In an embodiment, the alloy atoms may include at least one of titanium (Ti), nickel (Ni), or lanthanum (La).

In an embodiment, the first layer may have a thickness of about 60 nm to about 120 nm.

In an embodiment, the second layer may have a thickness of about 2 nm to about 12 nm.

In an embodiment, the transparent conductive oxide may include an indium tin oxide (ITO).

In an embodiment, the anti-oxidation layer may have a thickness of about 1 nm to about 5 nm.

In an embodiment, the first electrode may have a thickness of about 63 nm to about 137 nm.

In an embodiment, the at least one functional layer may include a first light-emitting layer configured to emit a first light and a second light-emitting layer disposed on the first light-emitting layer and configured to emit a second light that is different from the first light.

In an embodiment, the light-emitting element may include a first light-emitting element, a second light-emitting element, and a third light-emitting element, which are spaced apart from each other in one direction that is perpendicular to a thickness direction, wherein the first light-emitting element may emit red light, the second light-emitting element may emit green light, and the third light-emitting element may emit blue light.

In an embodiment, a method for manufacturing a display panel includes preparing a base layer, forming a first electrode including a first layer disposed on the base layer, a second layer disposed on the first layer, and an anti-oxidation layer disposed between the first layer and the second layer, forming a functional layer on the first electrode and forming a second electrode on the functional layer, wherein the forming of the first electrode includes forming a preliminary first layer by providing an aluminum alloy, forming a preliminary anti-oxidation layer on the preliminary first layer by providing titanium nitride (TiN), forming a preliminary second layer on the preliminary anti-oxidation layer by providing a transparent conductive oxide, forming the second layer by wet-etching the preliminary second layer and forming the first layer and the anti-oxidation layer by collectively etching the preliminary first layer and the preliminary anti-oxidation layer.

In an embodiment, when the atomic percentage is about 100 at %, the percentage of alloy atoms excluding aluminum atoms in the aluminum alloy may be about 0.01 at % to about 0.1 at %.

In an embodiment, the alloy atoms may include at least one of titanium (Ti), nickel (Ni), or lanthanum (La).

In an embodiment, the transparent conductive oxide may include an indium tin oxide (ITO), wherein an oxalic acid-based etching solution may be provided in the forming of the second layer.

In an embodiment, the preliminary first layer and the preliminary anti-oxidation layer may be dry-etched.

In an embodiment, in the forming of the first layer and the anti-oxidation layer, a fluorine gas or chlorine gas may be provided.

In an embodiment, an electronic apparatus includes a display panel and a lens system disposed opposite to the display panel, wherein the display panel includes a light-emitting element and a pixel defining film having a pixel opening defined therein, wherein the light-emitting element includes a first electrode exposed through the pixel opening, a second electrode disposed on the first electrode and at least one functional layer disposed between the first electrode and the second electrode, wherein the first electrode includes a first layer including an aluminum alloy a second layer including a transparent conductive oxide and an anti-oxidation layer including titanium nitride (TiN) and disposed between the first layer and the second layer, wherein, when the atomic percentage is about 100 at %, the percentage of alloy atoms excluding aluminum atoms in the aluminum alloy is about 0.01 at % to about 0.1 at %.

In an embodiment, the alloy atoms may include at least one of titanium (Ti), nickel (Ni), or lanthanum (La).

In an embodiment, the first layer may have a thickness of about 60 nm to about 120 nm, the second layer may have a thickness of about 2 nm to about 12 nm, and the anti-oxidation layer may have a thickness of about 1 nm to about 5 nm.

In an embodiment, the at least one functional layer may include a first light-emitting layer configured to emit a first light and a second light-emitting layer disposed on the first light-emitting layer and configured to emit a second light that is different from the first light.

In an embodiment, the light-emitting element may include a first light-emitting element, a second light-emitting element, and a third light-emitting element, which are spaced apart from each other in one direction that is perpendicular to a thickness direction, wherein the first light-emitting element may emit red light, the second light-emitting element may emit green light, and the third light-emitting element may emit blue light.

### BRIEF DESCRIPTION OF THE FIGURES

The accompanying drawings are included to provide a further understanding of the invention and are incorporated in and constitute a part of this specification. The drawings illustrate embodiments of the invention and, together with the description, serve to explain principles of the invention. In the drawings:

FIG. 1 is a perspective view of an electronic apparatus, according to an embodiment;

FIG. 2 is a perspective view of an electronic apparatus, according to an embodiment;

FIG. 3 is an exploded perspective view of an electronic apparatus, according to an embodiment;

FIG. 4 is a cross-sectional view of a portion of the electronic apparatus corresponding to line I-I′ of FIG. 3, according to an embodiment;

FIG. 5 is a cross-sectional view of a display panel, according to an embodiment;

FIG. 6 is a cross-sectional view of an enlarged region XX′ of the display panel of FIG. 5, according to an embodiment;

FIG. 7A is an image of a surface of an aluminum alloy, according to an embodiment;

FIG. 7B is an image of a surface of an aluminum alloy, according to an embodiment;

FIG. 7C is an image of a surface of aluminum, according to an embodiment;

FIG. 8A is an image of a cross section of aluminum, according to an embodiment;

FIG. 8B is an image of a cross section of aluminum, according to an embodiment;

FIG. 9 is a graph showing the result of evaluating reflectance according to wavelength, according to an embodiment;

FIG. 10 is a cross-sectional view of a display panel, according to an embodiment;

FIG. 11A is a flowchart showing a method of manufacturing a display panel, according to an embodiment;

FIG. 11B is a flowchart showing the method of manufacturing the display panel, according to an embodiment;

FIG. 12 schematically illustrates a step of manufacturing the display panel, according to an embodiment;

FIG. 13 schematically illustrates a step of manufacturing the display panel, according to an embodiment;

FIG. 14 schematically illustrates a step of manufacturing the display panel, according to an embodiment;

FIG. 15 schematically illustrates a step of manufacturing the display panel, according to an embodiment;

FIG. 16 schematically illustrates a step of manufacturing the display panel, according to an embodiment; and

FIG. 17 schematically illustrates a step of manufacturing the display panel, according to an embodiment.

### DETAILED DESCRIPTION

In the invention, various modifications can be made, various forms can be used, and specific embodiments will be illustrated in the drawings and described in detail in the text. However, this is not intended to limit the invention to a specific form disclosed, and it will be understood that all changes, equivalents, or substitutes which fall in the spirit and technical scope of the invention should be included.

In this specification, it will be understood that when an element (or region, layer, portion, etc.) is referred to as being related to another element such as being “on”, “connected to” and/or “coupled to” another element, it can be directly on, connected or coupled to the other element, or intervening elements may be present. For example, being “disposed directly on” may mean that two layers or two members are disposed without using an additional member such as an adhesive member, therebetween.

Like reference numerals refer to like elements throughout. In addition, in the drawings, the thicknesses, ratios, and dimensions of elements are exaggerated for effective description of the technical contents. As used herein, the term “and/or” includes any and all combinations that the associated configurations can define.

It will be understood that, although the terms first, second, etc. may be used herein to describe various elements, these elements should not be limited by these terms. These terms are only used to distinguish one element from another element. For example, a first element could be termed a second element without departing from the scope of the present invention. Similarly, the second element may also be referred to as the first element. The terms of a singular form include plural forms unless otherwise specified.

In addition, terms, such as “below”, “lower”, “above”, “upper” and the like, are used herein for ease of description to describe one element's relation to another element(s) as illustrated in the figures. The above terms are relative concepts and are described based on the directions indicated in the drawings.

It will be understood that the terms “include” and/or “have”, when used in this specification, specify the presence of stated features, integers, steps, operations, elements, components and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel, an electronic apparatus including the display panel and a method of manufacturing the display panel according to an embodiment will be described with reference to the drawings.

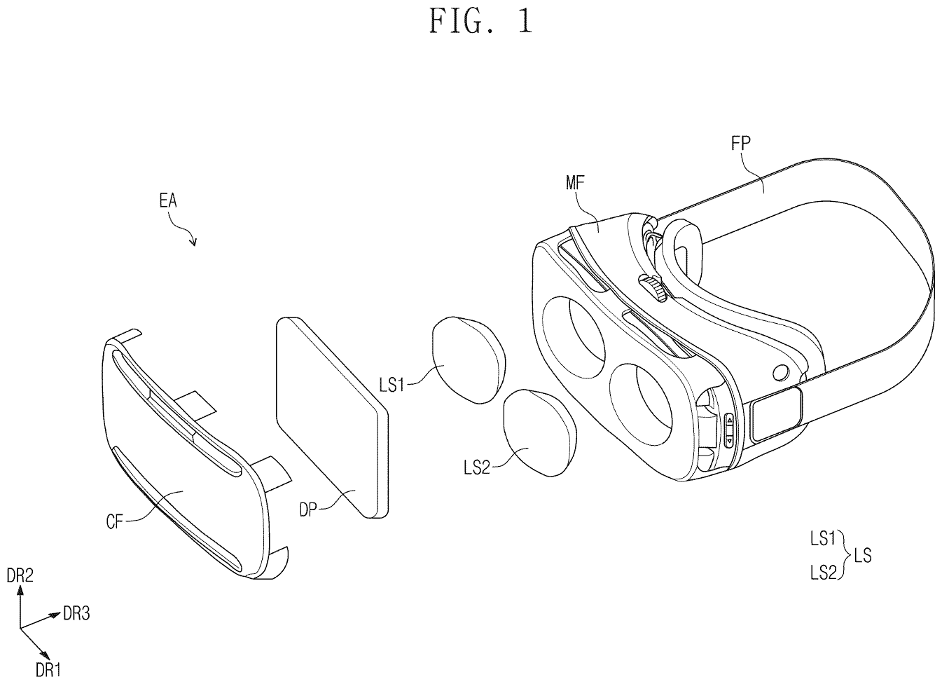

FIG. 1 is a perspective view illustrating an electronic apparatus EA according to an embodiment. The electronic apparatus EA may be activated according to an electrical signal. For example, the electronic apparatus EA may be a television, a monitor, an external billboard, a personal computer, a laptop computer, a mobile phone, a tablet, a game machine, a navigation system, and a wearable device, but the invention is not limited thereto.

In an embodiment, FIG. 1 illustrates a head-mounted display (HMD) device, which is a wearable device, as an example of the electronic apparatus EA. A head-mounted display device may be mounted on the head of a user to provide a screen on which an image and/or video is displayed to the user. The head-mounted display device may include a see-through type that provides augmented reality (AR) based on actual external objects and a see-closed type that provides virtual reality (VR) to a user on a screen independent of external objects.

In an embodiment and referring to FIG. 1, the electronic apparatus EA may include a display panel DP and a lens system LS disposed opposite to the display panel DP. In addition, the electronic apparatus EA may include a main frame MF, a cover frame CF, and a fixing part FP.

In an embodiment, the main frame MF may be a part worn on the face of a user. The main frame MF may have a shape corresponding to the shape of the user's head (or face). For example, the length of the fixing part FP may be adjusted according to the circumference of the user' head. The fixing part FP may have a structure for facilitating the mounting of the main frame MF to the user's head or face and include a strap, a belt, and the like. However, the invention is not limited thereto, and the fixing part FP may have various forms, such as a helmet or eyeglass temples, which are coupled to the main frame MF.

In an embodiment, the lens system LS, the display panel DP, and the cover frame CF may be mounted on the main frame MF. The main frame MF may include a space or structure in which the lens system LS and the display panel DP may be accommodated.

In an embodiment, the lens system LS may be disposed between the display panel DP and a user. The lens system LS may allow light emitted from the display panel DP to pass therethrough and provide the light to the user. For example, the lens system LS may include various types of lenses such as a multi-channel lens, a convex lens, a concave lens, a spherical lens, an aspherical lens, a single lens, a combined lens, a standard lens, a narrow-angle lens, a wide-angle lens, a fixed focus lens, and/or a variable focus lens.

In an embodiment, the lens system LS may include a first lens LS1 and a second lens LS2. The first lens LS1 and the second lens LS2 may be disposed to correspond to the positions of the user's left and right eyes. The first lens LS1 and the second lens LS2 may be accommodated inside the main frame MF.

In an embodiment, the display panel DP may be provided in a fixed state to the main frame MF or may be provided in a detachable state. Since the display panel DP according to an embodiment includes a first electrode EL1 (see FIG. 6), which will be described later, the display panel DP may exhibit excellent display quality. The display panel DP will be described in more detail later.

In an embodiment, the cover frame CF may be disposed on or adjacent to one surface of the display panel DP to protect the display panel DP. The cover frame CF and the lens system LS may be spaced apart from each other with the display panel DP interposed therebetween.

In an embodiment, FIG. 1 and the accompanying drawings illustrate first to third direction axes DR1 to DR3, respectively, and directions indicated by the first to third direction axes DR1, DR2, and DR3, respectively, described herein are relative concepts and may be converted into other directions. In addition, the directions indicated by the first to third direction axes DR1, DR2, and DR3, respectively, may be described as first to third directions, respectively, for which the same reference numerals may be used. In this specification, the first direction axis DR1 and the second direction axis DR2 are orthogonal to each other, and the third direction axis DR3 is a direction normal to a plane defined by the first direction axis DR1 and the second direction axis DR2.

In an embodiment, the thickness direction of the electronic apparatus EA may be parallel to the third direction axis DR3 which is a direction normal to a plane defined by the first and second direction axes DR1 and DR2, respectively. In this specification, the front (or top surface) and the rear surface (or bottom surface) of members constituting the electronic apparatus EA may be defined based on the third direction axis DR3. In this specification, the term “plane” means a plane parallel to the plane defined by the first and second direction axes DR1 and DR2, respectively, and the term “cross section” means a plane parallel to the third direction axis DR3.

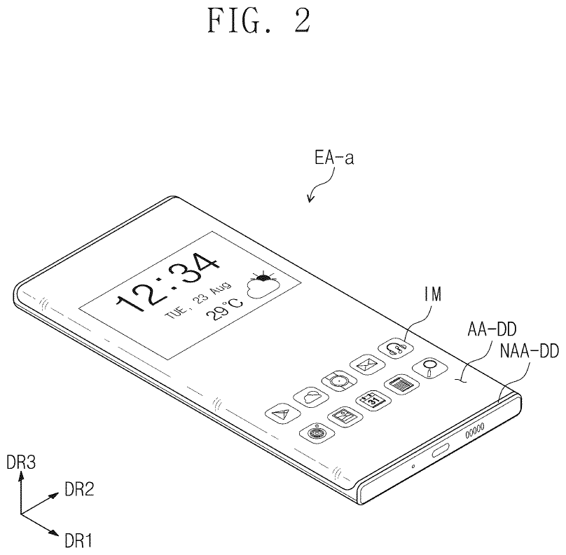

FIG. 2 is a perspective view illustrating an electronic apparatus according to another embodiment and illustrates a mobile phone as an example of an electronic apparatus EA-a. The electronic apparatus EA-a may display an image IM through a display region AA-DD. The display region AA-DD may include a plane defined by the first direction axis DR1 and the second direction axis DR2. The display region AA-DD may include a curved surface that is bent from at least one side of the plane defined by the first and second direction axes DR1 and DR2, respectively. However, this is an exemplary embodiment, and the shape of the display region AA-DD is not limited thereto. For example, the display region AA-DD may include only the plane, or the display region AA-DD may further include at least two, for example, four curved surfaces respectively bent from four side surfaces of the plane.

In an embodiment, a non-display region NAA-DD may be disposed adjacent to the display region AA-DD. The non-display region NAA-DD may surround the display region AA-DD. Accordingly, the shape of the display region AA-DD may be substantially defined by the non-display region NAA-DD. However, this is illustrated as an example, and the non-display region NAA-DD may be disposed to be adjacent to only one side of the display region AA-DD or may be omitted. The display region AA-DD may be provided in various shapes and is not limited to any one embodiment.

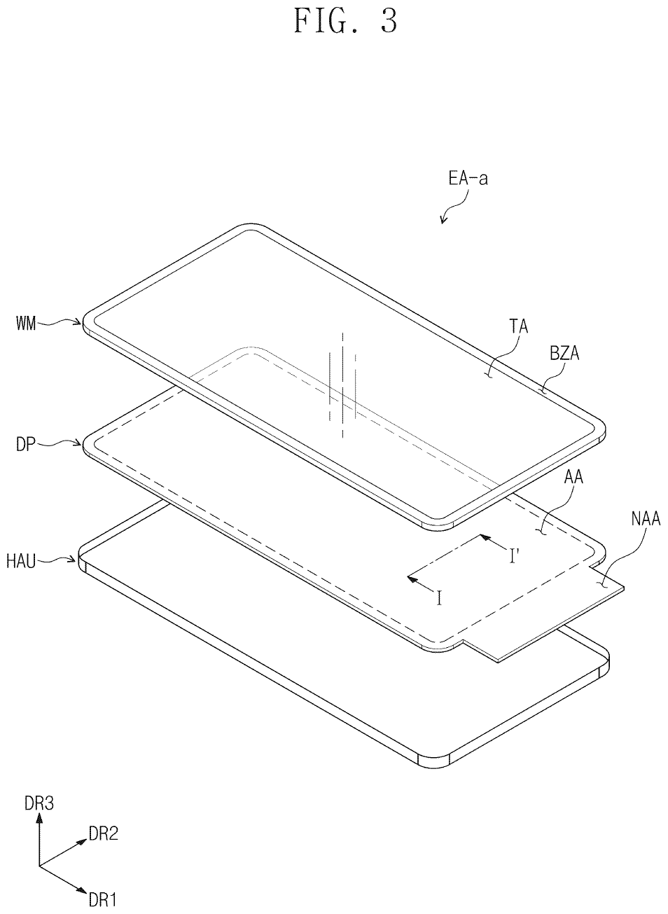

In an embodiment, FIG. 3 is an exploded perspective view of the electronic apparatus EA-a illustrated in FIG. 2. Referring to FIG. 3, the electronic apparatus EA-a may include a housing HAU, a display panel DP, and a window member WM. Hereinafter, the description of the display panel DP may be equally applied to the display panel DP illustrated in FIGS. 1 and 3.

In an embodiment, the housing HAU may include a material with relatively high rigidity. For example, the housing HAU may include a plurality of frames and/or plates composed of glass, plastic, and/or metal. The housing HAU may provide a predetermined accommodation space. The display panel DP may be located in the accommodation space and protected from an external impact.

In an embodiment, the window member WM may cover the entire outer side of the display panel DP. The window member WM may include a transmission region TA and a bezel region BZA. The front surface of the window member WM including the transmission region TA and the bezel region BZA may correspond to the front surface of the electronic apparatus EA-a. The transmission region TA may correspond to the display region AA-DD of the electronic apparatus EA-a illustrated in FIG. 2, and the bezel region BZA may correspond to the non-display region NAA-DD of the electronic apparatus EA-a illustrated in FIG. 2.

In an embodiment, the transmission region TA may be an optically transparent region. Compared to the transmission region TA, the bezel region BZA may have a relatively low light transmittance. The bezel region BZA may have a predetermined color. The bezel region BZA may be located adjacent to and may surround the transmission region TA. The bezel region BZA may define the shape of the transmission region TA. However, the invention is not limited to what is illustrated, and the bezel region BZA may be disposed to be adjacent to only one side of the transmission region TA, or a portion thereof may be omitted.

In an embodiment, the window member WM may include a window. The window may include an optically transparent insulating material. The window may be a glass substrate or a polymer substrate. For example, the window may be a tempered glass substrate that has been tempered. Alternatively, the window may be made of polyimide, polyacrylate, polymethyl methacrylate, polycarbonate, polyethylene naphthalate, polyvinylidene chloride, polyvinylidene difluoride, polystyrene, ethylene-vinyl alcohol copolymer, or a combination thereof. However, these are exemplary, and the material included in the window is not limited thereto.

In an embodiment, an active region AA and a peripheral region NAA may be defined in the display panel DP. The active region AA may correspond to the display region AA-DD of the electronic apparatus EA-a illustrated in FIG. 2, and the peripheral region NAA may correspond to the non-display region NAA-DD of the electronic apparatus EA-a illustrated in FIG. 2.

In an embodiment, the active region AA may be activated according to an electrical signal. The peripheral region NAA may be positioned to be adjacent to at least one side of the active region AA.

In an embodiment, the peripheral region NAA may be disposed to surround the active region AA. However, the invention is not limited thereto, and unlike what is illustrated in FIG. 3, a portion of the peripheral region NAA may be omitted. A driving circuit, a driving line, and/or the like for driving the active region AA may be disposed in the peripheral region NAA.

In an embodiment, the display panel DP may be a component that substantially generates an image. The display panel DP may be a light-emitting display panel, and for example, the display panel DP may be an organic light-emitting display panel, an inorganic light-emitting display panel, a quantum dot display panel, a micro LED display panel, or a nano LED display panel. The display panel DP may also be referred to as a display layer.

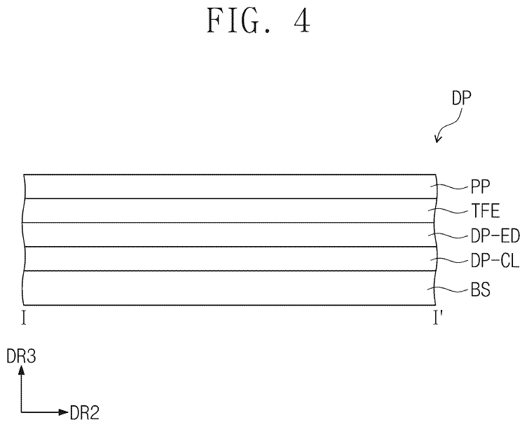

In an embodiment, FIG. 4 is a cross-sectional view illustrating a portion corresponding to the line I-I′ of FIG. 3. FIG. 4 may be a cross-sectional view schematically illustrating a configuration of the display panel DP. Referring to FIG. 4, the display panel DP may include a base layer BS, a circuit layer DP-CL, a display element layer DP-ED, and an encapsulation layer TFE. In addition, the display panel DP may further include an optical layer PP.

In an embodiment, the base layer BS may be a member configured to provide a base surface on which the circuit layer DP-CL is disposed. The base layer BS may be a rigid substrate or a flexible substrate capable of being bent, folded, or rolled. The base layer BS may be a glass substrate, a metal substrate, or a polymer substrate. However, the invention is not limited thereto, and the base layer BS may be an inorganic layer, an organic layer, or a composite material layer.

In an embodiment, the circuit layer DP-CL may be disposed on the upper side of the base layer BS. The circuit layer DP-CL may include an insulating layer, a semiconductor pattern, a conductive pattern, a signal line, and/or the like. After an insulating layer, a semiconductor layer, and a conductive layer are formed on the base layer BS by a method such as coating or deposition, the insulating layer, the semiconductor layer, and the conductive layer may be selectively patterned through a plurality of photolithography processes. Hereafter, the semiconductor pattern, the conductive pattern, and the signal line included in the circuit layer DP-CL may be formed.

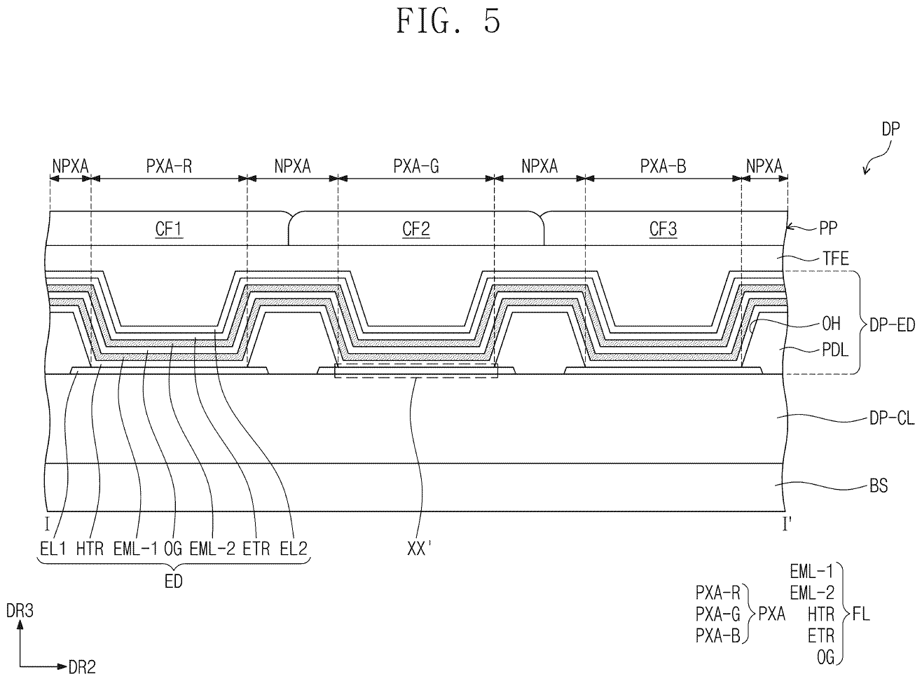

In an embodiment, the display element layer DP-ED may be disposed on the upper side of the circuit layer DP-CL. The display element layer DP-ED may include a light-emitting element ED (see FIG. 5) to be described later. For example, the display element layer DP-ED may include an organic light-emitting material, an inorganic light-emitting material, an organic-inorganic light-emitting material, a quantum dot, a quantum rod, a micro LED, and/or a nano LED.

In an embodiment, the encapsulation layer TFE may be disposed on the upper side of the display element layer DP-ED. The encapsulation layer TFE may protect the display element layer DP-ED from moisture, oxygen, and foreign substances such as dust particles. The encapsulation layer TFE may include at least one insulating layer.

In an embodiment, the optical layer PP may be disposed on the display panel DP to control light reflected from the display panel DP by external light. The optical layer PP may include, for example, a polarization layer or a color filter layer.

FIG. 5 is a cross-sectional view illustrating a display panel DP according to an embodiment. The base layer BS may have a single-layered or multi-layered structure. For example, the base layer BS may include a first synthetic resin layer, a multi-layered or single-layered intermediate layer, and a second synthetic resin layer which are sequentially stacked. The intermediate layer may be referred to as a base barrier layer. The intermediate layer may include a silicon oxide (SiOx) layer and an amorphous silicon (a-Si) layer disposed on the silicon oxide layer, but the invention is not particularly limited thereto. For example, the intermediate layer may include at least one of a silicon oxide layer, a silicon nitride layer, a silicon oxy nitride layer, or an amorphous silicon layer.

In an embodiment, each of the first and second synthetic resin layers may include a polyimide-based resin. In addition, each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, a “˜˜”-based resin means to include a functional group of “˜˜”. For example, the “perylene”-based resin may include a “perylene” group.

In an embodiment, the circuit layer DP-CL may be disposed on the base layer BS. The circuit layer DP-CL may include a plurality of transistors (not illustrated). Each of the transistors (not illustrated) may include a control electrode, an input electrode, and an output electrode. For example, the circuit layer DP-CL may include a switching transistor and a driving transistor for driving the light-emitting element ED of the display element layer DP-ED.

In an embodiment, the display element layer DP-ED may include a light-emitting element ED and a pixel defining film PDL. The light-emitting element ED includes a first electrode EL1, a second electrode EL2 disposed on the first electrode EL1, and at least one functional layer FL disposed between the first electrode EL1 and the second electrode EL2.

In an embodiment, the first electrode EL1 may be an anode. In an embodiment, the first electrode EL1 may include a first layer LL1 (see FIG. 6), an anti-oxidation layer LL3 (see FIG. 6), and a second layer LL2 (see FIG. 6), which will be described later. Accordingly, the first electrode EL1 may be formed as a microstructure which exhibits excellent reliability, and the display panel DP including the first electrode EL1 may exhibit excellent display quality. The first electrode EL1 will be described in more detail later.

In an embodiment, the pixel defining film PDL may have a transparent property or a property of absorbing light. For example, the pixel defining film PDL that absorbs light may include a black coloring agent. The black coloring agent may include a black dye or black pigment. The black coloring agent may include carbon black, a metal such as chromium, or an oxide thereof. The pixel defining film PDL may correspond to a shielding pattern having light blocking characteristics.

In an embodiment, the pixel defining film PDL may cover a portion of the first electrode EL1. For example, a pixel opening OH exposing a portion of the first electrode EL1 may be defined in the pixel defining film PDL. The pixel defining film PDL may increase the distance between an edge of the first electrode EL1 and the second electrode EL2. Therefore, the pixel defining film PDL may prevent an arc or the like from occurring at the edge of the first electrode EL1.

In an embodiment, the second electrode EL2 may be a cathode. The second electrode EL2 may be disposed as a common layer. The second electrode EL2 may be referred to as a common electrode. A common voltage may be provided to the second electrode EL2. For example, the second electrode EL2 may include at least one selected from the group consisting of Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

In an embodiment, at least one functional layer FL may include a first light-emitting layer EML-1 and a second light-emitting layer EML-2 disposed on the first light-emitting layer EML-1. The first light-emitting layer EML-1 and the second light-emitting layer EML-2 may be disposed between the first electrode EL1 and the second electrode EL2. In addition, at least one functional layer FL may further include a hole transport region HTR, an electron transport region ETR, and a light-emitting auxiliary layer OG.

In an embodiment, the light-emitting element ED may have a tandem structure including a plurality of light-emitting layers EML-1 and EML-2. The first light-emitting layer EML-1 and the second light-emitting layer EML-2 may be provided as a common layer. However, the invention is not limited thereto, and the light-emitting element ED may include a single light-emitting layer (a first light-emitting layer or a second light-emitting layer) disposed as a common layer.

In an embodiment, each of the first light-emitting layer EML-1 and the second light-emitting layer EML-2 may include an organic light-emitting material and/or an inorganic light-emitting material. The first light-emitting layer EML-1 may emit a first light, and the second light-emitting layer EML-2 may emit a second light that is different from the first light. For example, the first light-emitting layer EML-1 may emit light in a wavelength range of about 450 nm to about 570 nm. The second light-emitting layer EML-2 may emit light in a wavelength range of about 590 nm to about 750 nm. However, this is exemplary, and the wavelengths of light emitted from the first and second light-emitting layers EML-1 and EML-2, respectively, are not limited thereto. Alternatively, the first light-emitting layer EML-1 and the second light-emitting layer EML-2 may emit light of the same wavelength range.

In an embodiment, the light-emitting element ED including the first light-emitting layer EML-1 and the second light-emitting layer EML-2 may emit white light. However, the invention is not limited thereto, and the light-emitting element ED including the first light-emitting layer EML-1 and the second light-emitting layer EML-2 may emit blue light.

In an embodiment, the hole transport region HTR may be disposed between the first electrode EL1 and the first light-emitting layer EML-1. The hole transport region HTR may include at least one of a hole injection layer, a hole transport layer, or an electron blocking layer. The hole transport region HTR may include a known hole injection material and/or hole transport material. The hole transport region HTR may be disposed as a common layer. However, the invention is not limited thereto, and the hole transport region HTR may be patterned and provided in the pixel opening OH.

In an embodiment, the electron transport region ETR may be disposed between the second light-emitting layer EML-2 and the second electrode EL2. The electron transport region ETR may include at least one of an electron injection layer, an electron transport layer, or a hole blocking layer. The electron transport region ETR may include a known electron injection material and/or electron transport material. The electron transport region ETR may be disposed as a common layer. However, the invention is not limited thereto, and the electron transport region ETR may be patterned and provided in the pixel opening OH.

In an embodiment, the light-emitting auxiliary layer OG may be disposed between the first light-emitting layer EML-1 and the second light-emitting layer EML-2. The light-emitting auxiliary layer OG may include a single layer or multiple layers. The light-emitting auxiliary layer OG may include a charge generation layer. In addition, the light-emitting auxiliary layer OG may further include a hole transport region disposed above the charge generation layer and an electron transport region disposed below the charge generation layer. The light-emitting auxiliary layer OG may be provided as a common layer. However, the invention is not limited thereto, and the light-emitting auxiliary layer OG may be patterned and provided in the pixel opening OH.

In an embodiment, the encapsulation layer TFE may cover the light-emitting element ED. The encapsulation layer TFE may seal the display element layer DP-ED. The encapsulation layer TFE may be disposed on the second electrode EL2 and fill the pixel opening OH.

In an embodiment, the encapsulation layer TFE may be a thin film encapsulation layer. The encapsulation layer TFE may be a single layer or a plurality of layers stacked on each other. The encapsulation layer TFE may include at least one insulating layer. The encapsulation layer TFE according to an embodiment may include at least one inorganic film (hereinafter referred to as an encapsulation inorganic film). In addition, the encapsulation layer TFE according to an embodiment may include at least one organic film (hereinafter referred to as an encapsulation organic film) and at least one encapsulation inorganic film.

In an embodiment, the encapsulation inorganic film may protect the display element layer DP-ED from moisture/oxygen, and the encapsulation organic film may protect the display element layer DP-ED from foreign substances such as dust particles. The encapsulation inorganic film may include silicon nitride, silicon oxynitride, silicon oxide, titanium oxide, and/or aluminum oxide, and the invention is not particularly limited thereto. The encapsulation organic film may include an acrylic-based compound, an epoxy-based compound, or the like. The encapsulation organic film may include a photopolymerizable organic material and the invention is not particularly limited thereto.

In an embodiment, the display panel DP may include a light-emitting region PXA and a non-light-emitting region NPXA. The light-emitting region PXA may be a region from which light generated by the light-emitting element ED is emitted. The light-emitting region PXA may be divided by the pixel defining film PDL. The non-light-emitting regions NPXA may be regions disposed between adjacent light-emitting regions PXA and may correspond to the pixel defining films PDL. The light-emitting region PXA may correspond to a pixel.

In an embodiment, the light-emitting region PXA may include a red light-emitting region PXA-R, a green light-emitting region PXA-G, and a blue light-emitting region PXA-B. The red light-emitting region PXA-R, the green light-emitting region PXA-G, and the blue light-emitting region PXA-B may be spaced apart from each other on a plane.

As an example, in an embodiment, FIG. 5 illustrates that the optical layer PP includes first to third filters CF1, CF2, and CF3, respectively. The first filter CF1 may be disposed to correspond to the red light-emitting region PXA-R, the second filter CF2 may be disposed to correspond to the green light-emitting region PXA-G, and the third filter CF3 may be disposed to correspond to the blue light-emitting region PXA-B.

For example, in an embodiment, the first filter CF1 may be a red filter, the second filter CF2 may be a green filter, and the third filter CF3 may be a blue filter. Each of the filters CF1, CF2, and CF3 may include a polymeric photosensitive resin and a pigment or dye. The first filter CF1 may include a red pigment or dye, the second filter CF2 may include a green pigment or dye, and the third filter CF3 may include a blue pigment or dye. However, the invention is not limited thereto, and the third filter CF3 may not include a pigment or dye. The third filter CF3 may include a polymeric photosensitive resin and may not include a pigment or dye. The third filter CF3 may be optically transparent. The third filter CF3 may be formed of a transparent photosensitive resin.

In an embodiment, a portion of each of the first to third filters CF1, CF2, and CF3, respectively, may be disposed in the non-light-emitting region NPXA. However, the invention is not limited thereto, and the first to third filters CF1, CF2, and CF3, respectively, may not be disposed in the non-light-emitting region NPXA.

In an embodiment, a light blocking part (not illustrated) may be disposed between two adjacent filters among the first to third filters CF1, CF2, and CF3, respectively. The light blocking part may be a black matrix. The light blocking part may include an organic light blocking material or an inorganic light blocking material which includes a black pigment or a black dye. The light blocking part may prevent a light leakage phenomenon and divide boundaries between adjacent filters CF1, CF2, and CF3.

FIG. 6 is a cross-sectional view illustrating an enlarged region XX′ of FIG. 5, according to an embodiment. FIG. 6 may be a cross-sectional view specifically illustrating a configuration of the first electrode EL1, according to an embodiment.

In an embodiment and referring to FIG. 6, the first electrode EL1 may include a first layer LL1, a second layer LL2 disposed above the first layer LL1, and an anti-oxidation layer LL3 disposed between the first layer LL1 and the second layer LL2. A thickness T4 of the first electrode EL1 including the first layer LL1, the anti-oxidation layer LL3, and the second layer LL2 may be about 63 nm to about 137 nm. Since the first electrode EL1 having a thickness of more than about 137 nm is not easy to be patterned into a microstructure, ultra-high resolution may not be achieved. In an embodiment, the first electrode EL1 having the thickness T4 of about 63 nm to about 137 nm may be patterned into a microstructure through dry-etching. Accordingly, the display panel DP including the first electrode EL1 may achieve ultra-high resolution.

In an embodiment, the head-mounted display device (electronic apparatus, EA) illustrated in FIG. 1 requires ultra-high resolution for implementing virtual reality and augmented reality, and the display panel DP including the first electrode EL1 may achieve an ultra-high resolution of about 3000 ppi or more. The electronic apparatus EA including the display panel DP according to an embodiment may exhibit excellent display quality.

In an embodiment, the first layer LL1 may include an aluminum alloy. The first layer LL1 may include an aluminum alloy composed of aluminum atoms and alloy atoms. In this specification, the alloy atoms refer to atoms other than aluminum atoms among atoms constituting the aluminum alloy. The alloy atom may be single or plural. The aluminum alloy constituting the first layer LL1 may include at least one of titanium (Ti), nickel (Ni), or lanthanum (La) as an alloy atom. For example, the first layer LL1 may include an alloy composed of aluminum and titanium. Alternatively, the first layer LL1 may include an alloy composed of aluminum, nickel, and lanthanum.

In an embodiment, in the first layer LL1, when the atomic percentage of the aluminum alloy is about 100 at % (atomic percent), the percentage of the alloy atoms excluding the aluminum atoms may be about 0.01 at % to about 0.1 at %. In the first layer LL1 in which the percentage of the alloy atoms excluding the aluminum atoms is about 0.01 at % or more, a hillock may be prevented from occurring. The hillock may be a protruding surface of a component. The first layer LL1 in which the percentage of the alloy atoms excluding the aluminum atoms is about 0.1 at % or less may maintain resistance and exhibit excellent light reflectance. The first layer LL1 may reflect light directed downward among light generated from the first and second light-emitting layers EML-1 and EML-2, respectively, and make the light be directed upward. Accordingly, display quality may be improved as the light reflectance of the first layer LL1 is higher.

In an embodiment, when the percentage of the alloy atoms is less than about 0.01 at %, the aluminum alloy is vulnerable to heat and a hillock occurs in a high-temperature process. The manufacturing process of the display panel DP may include forming the pixel defining film PDL after forming the first electrode EL1, and the forming of the pixel defining film PDL may be performed at a high temperature of about 250° C. or higher. When the percentage of the alloy atoms is less than about 0.01 at %, the aluminum alloy is not suitable as a first electrode because a hillock occurs in a process at a high temperature of 250° C. or higher. When the percentage of the alloy atoms exceeds about 0.1 at %, the resistance of the first layer increases and the reflectance of light decreases. When the light reflectance of the first layer is reduced, the light directed upward is reduced and display quality is deteriorated.

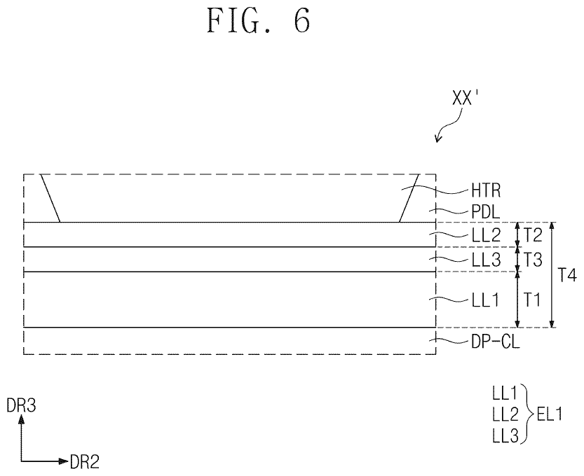

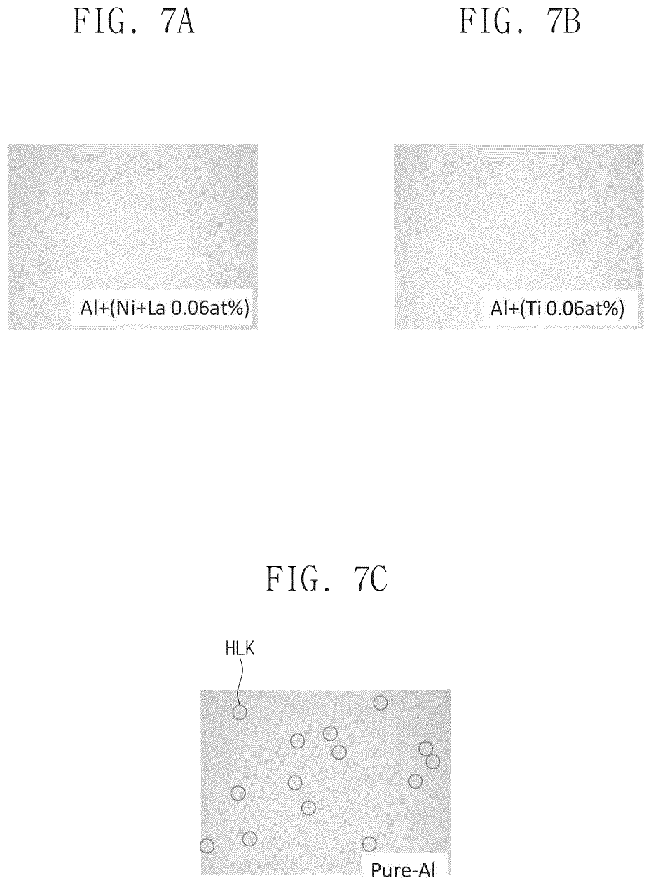

FIGS. 7A to 7C are images of an aluminum alloy or aluminum after a heat treatment process is performed at a temperature of about 250° C., according to an embodiment. FIGS. 7A and 7B are images of a surface of an aluminum alloy including alloy atoms, and FIG. 7C is an image of a surface of aluminum. FIG. 7C is a photograph of a single piece of aluminum without including alloy atoms.

In an embodiment, the aluminum alloy of FIG. 7A is formed of aluminum atoms and alloy atoms and includes nickel and lanthanum as alloy atoms. In the aluminum alloy of FIG. 7A, the atomic percentage of alloy atoms including nickel and lanthanum is about 0.06 at %. The aluminum alloy of FIG. 7B is formed of aluminum and alloy atoms and includes titanium as an alloy atom. In the aluminum alloy of FIG. 7B, the atomic percentage of titanium is about 0.06 at %. The aluminum alloys of FIGS. 7A and 7B satisfy the atomic percentages of alloy atoms according to an embodiment.

Compared to FIGS. 7A and 7B, it can be seen that a hillock HLK occurs in FIG. 7C, according to an embodiment. As the aluminum of FIG. 7C does not include alloy atoms, it is vulnerable to heat, thus causing a hillock to occur. Unlike this, it can be seen that a hillock does not occur in the aluminum alloys of FIGS. 7A and 7B which satisfy the atomic percentage of the alloy atoms according to an embodiment. Therefore, it is determined that the first layer LL1 formed of the aluminum alloy, which satisfies the percentage of alloy atoms according to an embodiment, will exhibit excellent heat resistance.

In an embodiment and referring back to FIG. 6, a thickness T1 of the first layer LL1 may be about 60 nm to about 120 nm. For example, the thickness T1 of the first layer LL1 may be about 100 nm. The surface roughness of the first layer having a thickness of more than about 120 nm will increase due to the increase in size of the aluminum particles. When the surface roughness is increased, diffused reflection occurs, and the diffused reflection causes display quality deterioration. In addition, the first layer having a thickness of more than about 120 nm is not easily formed by dry-etching and may not be patterned into a microstructure.

In an embodiment, light passes through the first layer having a thickness of less than about 60 nm, and light directed upward is reduced, thereby causing display quality deterioration In an embodiment, the first layer LL1 having the thickness T1 of about 60 nm to about 120 nm exhibits low transmittance and excellent light reflectance, thereby improving display quality.

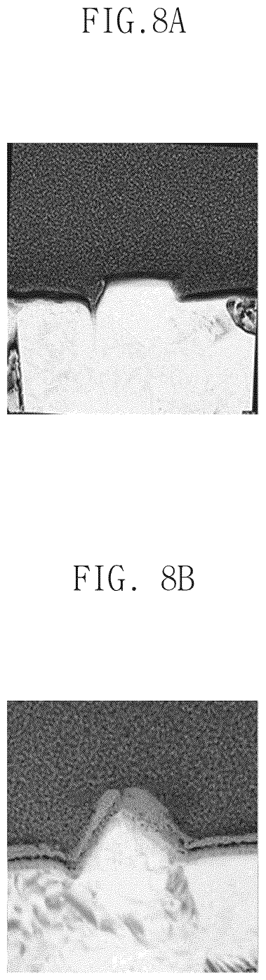

FIGS. 8A and 8B are images of the cross sections of the first layer formed of aluminum having a thickness of about 600 nm, according to an embodiment. Referring to FIGS. 8A and 8B, it can be seen that as aluminum having a thickness of about 600 nm is formed with a very large thickness and includes large aluminum particles, the surface thereof is not uniform and the surface roughness thereof is increased. When the surface roughness is increased, diffused reflection occurs and display quality is deteriorated.

In an embodiment, referring back to FIG. 6, the second layer LL2 may include a transparent conductive oxide (TCO). The second layer LL2 may include a material having excellent hole injection characteristics. The hole transport region HTR may be disposed on the second layer LL2. For example, the second layer LL2 may include an indium tin oxide (ITO).

In an embodiment, a thickness T2 of the second layer LL2 may be about 2 nm to about 12 nm. For example, the thickness T2 of the second layer LL2 may be about 5 nm. A second layer having a thickness of less than 2 nm is difficult to form with a uniform thickness, and a second layer having a thickness of more than 12 nm is not stably formed due to self-stress. In an embodiment, the second layer LL2 having the thickness T2 of about 2 nm to about 12 nm may be formed with a uniform thickness and exhibit excellent processability.

In an embodiment, the anti-oxidation layer LL3 may be directly disposed between the first layer LL1 and the second layer LL2. In this specification, when one component is directly disposed between other components, it means that a third component is not disposed between the one component and the other components. That is, when one component is directly disposed between other components, it means that the one component and the other components are in contact with each other.

In an embodiment, the anti-oxidation layer LL3 may be a layer that prevents formation of oxide due to contact between the first layer LL1 and the second layer LL2. When an anti-oxidation layer is not included, the first layer including an aluminum alloy and the second layer including an indium tin oxide come into contact with each other and an aluminum oxide film is formed between the first layer and the second layer. The aluminum oxide film absorbs light, thus degrading display quality and increasing the driving voltage of a light-emitting element. Unlike this, in an embodiment, the first electrode EL1 including the anti-oxidation layer LL3 disposed between the first layer LL1 and the second layer LL2 may improve display quality. In addition, the light-emitting element ED (see FIG. 5) including the first electrode EL1 including the anti-oxidation layer LL3 disposed between the first layer LL1 and the second layer LL2 may prevent an increase in the driving voltage.

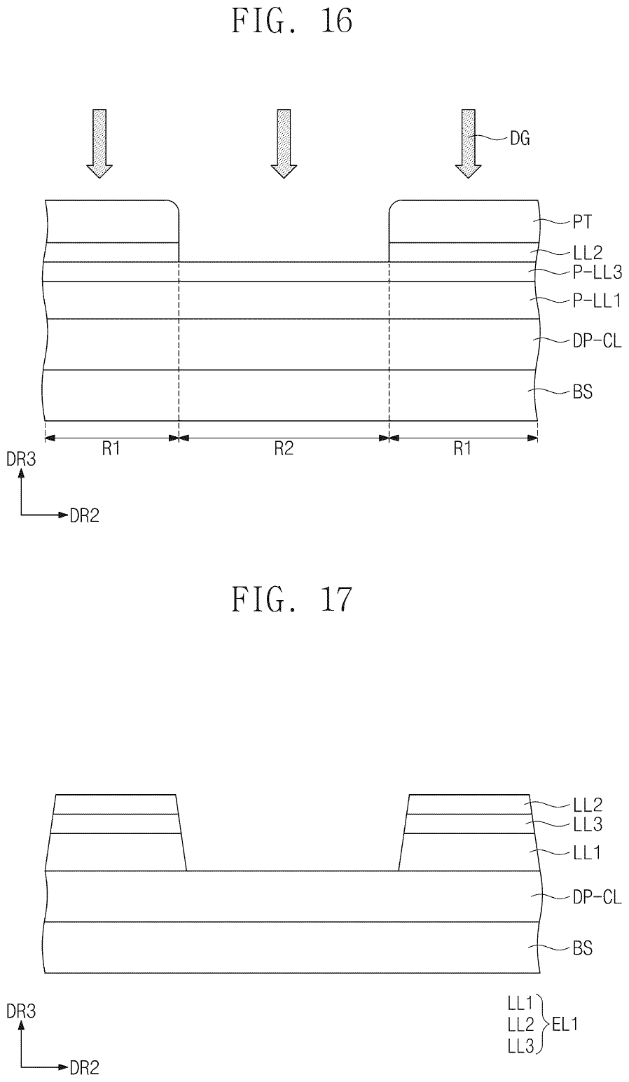

In an embodiment, the anti-oxidation layer LL3 may include titanium nitride (TiN). In a method of manufacturing a display panel according to an embodiment to be described later, a preliminary anti-oxidation layer P-LL3 (see FIG. 16) formed of titanium nitride may be etched in the same step as a preliminary first layer P-LL1 (see FIG. 16) including an aluminum alloy. The anti-oxidation layer LL3 may be formed from the preliminary anti-oxidation layer P-LL3 (see FIG. 16), and the first layer LL1 may be formed from the preliminary first layer P-LL1. Accordingly, the method of manufacturing the display panel according to an embodiment may exhibit excellent manufacturing efficiency. The method of manufacturing the display panel according to an embodiment will be described in more detail later.

In an embodiment, a thickness T3 of the anti-oxidation layer LL3 may be about 1 nm to about 5 nm. An anti-oxidation layer having a thickness of less than about 1 nm is not easy to form, and an anti-oxidation layer having a thickness of more than about 5 nm has a high light absorption rate, thereby causing display quality deterioration. In an embodiment, the anti-oxidation layer LL3 having the thickness T3 of about 1 nm to about 5 nm may be easily formed, thereby improving display quality.

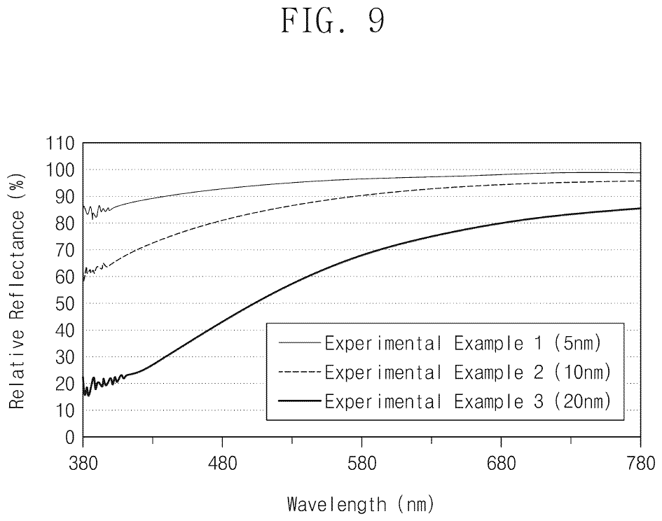

FIG. 9 is a graph showing the result of evaluating light reflectance according to wavelength in Experimental Examples 1 to 3 in which the thicknesses T3 of the anti-oxidation layer LL3 are different from each other. In an embodiment, each of Experimental Examples 1 to 3 includes the first layer LL1 and the anti-oxidation layer LL3, and the thickness of the first layer is about 60 nm. In Experimental Examples 1 to 3, only the thicknesses of the anti-oxidation layer LL3 are different from each other. A relative reflectance in FIG. 9 represents a relative light reflectance when the light reflectance of the first layer LL1, which does not include the anti-oxidation layer LL3, is about 100%.

In an embodiment, Experimental Example 2 includes an anti-oxidation layer having a thickness of about 10 nm, and Experimental Example 3 includes an anti-oxidation layer having a thickness of about 20 nm. Experimental Example 1 includes an anti-oxidation layer having a thickness of about 5 nm and satisfies the thickness range of the anti-oxidation layer LL3 according to an embodiment. The thickness T3 of the anti-oxidation layer LL3 according to an embodiment may be about 1 nm to about 5 nm.

In an embodiment and referring to FIG. 9, it can be seen that the relative reflectance of Experimental Example 1 is higher than those of Experimental Examples 2 and 3. It can be seen that Experimental Example 1 exhibits excellent light reflectance as it includes an anti-oxidation layer which satisfies the range of thickness according to an embodiment. It can be seen that Experimental Examples 2 and 3 exhibit low light reflectance as they include an anti-oxidation layer formed with a relatively large thickness, thereby increasing the light absorption rates thereof. Therefore, in an embodiment, it is determined that the anti-oxidation layer LL3 having the thickness T3 of about 1 nm to about 5 nm may improve display quality.

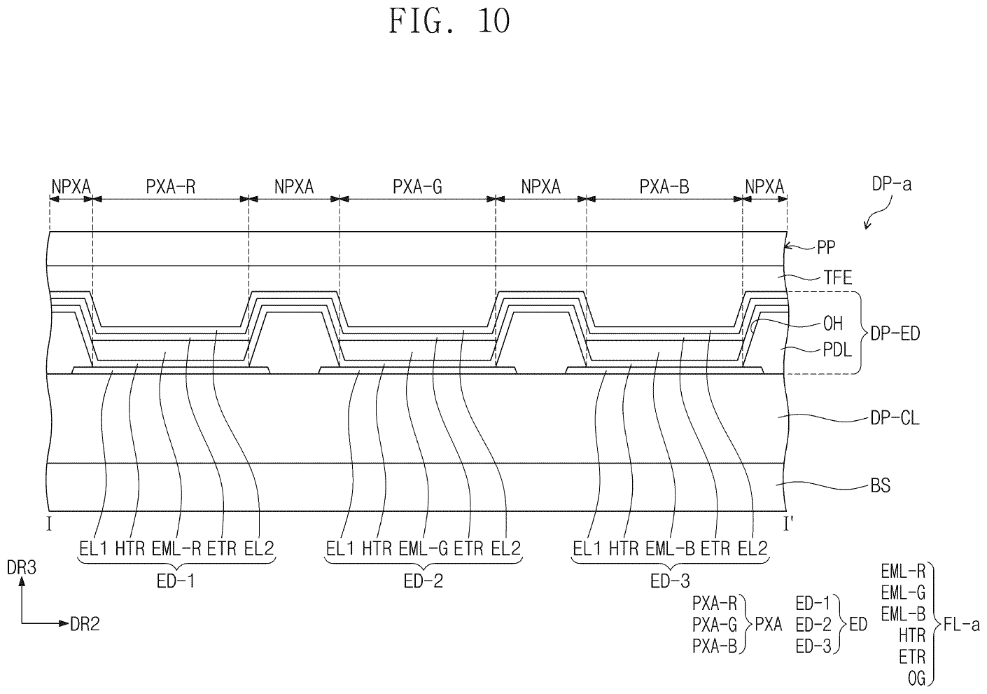

FIG. 10 is a cross-sectional view illustrating a display panel DP-a according to another embodiment. Hereinafter, in the description of FIG. 10, the contents overlapping those described with reference to FIGS. 1 to 9 will not be described again, and differences will be mainly described.

In an embodiment, compared to the display panel DP illustrated in FIG. 5, the display panel DP-a illustrated in FIG. 10 is different therefrom in that the light-emitting element ED includes first to third light-emitting elements ED-1, ED-2, and ED-3, respectively. In FIG. 10, the optical layer PP may include a polarization layer or the first to third filters CF1, CF2, and CF3, respectively, illustrated in FIG. 5.

In an embodiment, the first to third light-emitting elements ED-1, ED-2, and ED-3, respectively, may be spaced apart from each other in the second direction DR2 to be perpendicular to the thickness direction DR3. Each of the first to third light-emitting elements ED-1, ED-2, and ED-3, respectively, may include a first electrode EL1, a second electrode EL2 disposed on the first electrode EL1, and a functional layer FL-a disposed between the first electrode EL1 and the second electrode EL2. Compared to the functional layer FL of FIG. 5, the functional layer FL-a of FIG. 10 is different therefrom in including a red light-emitting layer EML-R, a green light-emitting layer EML-G, and a blue light-emitting layer EML-B which are patterned and provided in the pixel opening OH.

In an embodiment, the first light-emitting element ED-1 may include a red light-emitting layer EML-R and emit red light. The first light-emitting element ED-1 may be disposed to correspond to the red light-emitting region PXA-R. The second light-emitting element ED-2 may include a green light-emitting layer EML-G and emit green light. The second light-emitting element ED-2 may be disposed to correspond to the green light-emitting region PXA-G. The third light-emitting element ED-3 may include a blue light-emitting layer EML-B and emit blue light. The third light-emitting element ED-3 may be disposed to correspond to the blue light-emitting region PXA-B.

In an embodiment, although FIG. 10 illustrates that each of the first to third light-emitting elements ED-1, ED-2, and ED-3, respectively, includes one light-emitting layer, the invention is not limited thereto. For example, each of the first to third light-emitting elements ED-1, ED-2, and ED-3, respectively, may include a plurality of light-emitting layers configured to emit light of the same wavelength range.

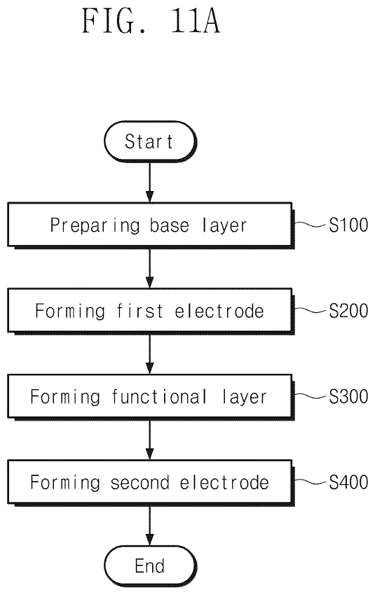

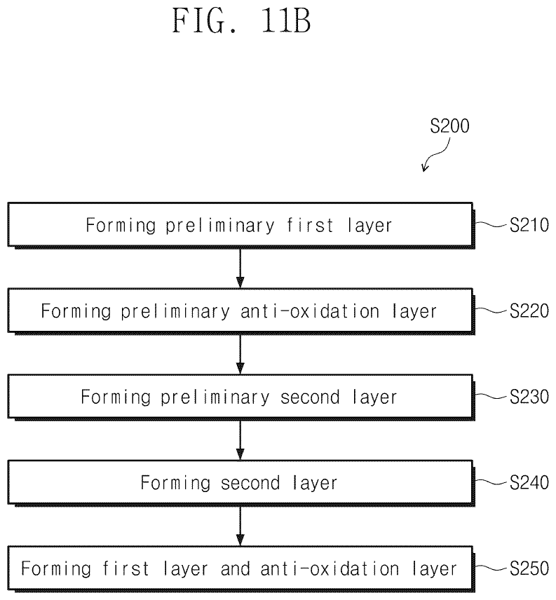

The display panel may be formed by a method of manufacturing a display panel according to an embodiment. FIGS. 11A and 11B are flowcharts showing a method of manufacturing a display panel according to an embodiment, and FIGS. 12 to 17 schematically illustrate steps of manufacturing the display panel according to an embodiment. Hereinafter, in the description of FIGS. 11A to 17, the contents overlapping those described with reference to FIGS. 1 to 10 will not be described again, and differences will be mainly described.

Referring to FIG. 11A, the method of manufacturing the display panel according to an embodiment may include preparing a base layer (S100), forming a first electrode (S200), forming a functional layer (S300), and forming a second electrode (S400). Although not illustrated, the method of manufacturing the display panel DP or DP-a according to an embodiment may further include forming a pixel defining film PDL (see FIGS. 5 and 10) between forming a first electrode EL1 (see FIGS. 5 and 10) and forming a functional layer FL or FL-a (see FIGS. 5 and 10).

In an embodiment and referring to FIG. 11B, the forming of the first electrode (S200) may include forming a preliminary first layer (S210), forming a preliminary anti-oxidation layer (S220), forming a preliminary second layer (S230), forming a second layer (S240), and forming a first layer and an anti-oxidation layer (S250). FIGS. 12 to 17 may schematically illustrate the forming of the first electrode (S200), according to an embodiment.

In an embodiment and referring to FIG. 12, a circuit layer DP-CL may be formed on the base layer BS, and a preliminary first layer P-LL1, a preliminary anti-oxidation layer P-LL3, and a preliminary second layer P-LL2 may be sequentially formed on the circuit layer DP-CL. The preliminary first layer P-LL1 may be formed by providing an aluminum alloy composed of aluminum atoms and alloy atoms. The preliminary first layer P-LL1 may be formed by a sputtering method. For example, the alloy atoms may include at least one of titanium (Ti), nickel (Ni), or lanthanum (La). In an embodiment, the percentage of the alloy atoms excluding the aluminum atoms in the aluminum alloy may be about 0.01 at % to about 0.1 at %. The preliminary first layer P-LL1 formed of the aluminum alloy in which the percentage of the alloy atoms excluding the aluminum atoms is about 0.01 at % to about 0.1 at % may exhibit excellent heat resistance. Accordingly, the first layer LL1 formed from the preliminary first layer P-LL1 may prevent a hillock from occurring in a high-temperature process in which the pixel defining film PDL or the like is formed.

In an embodiment, the preliminary anti-oxidation layer P-LL3 may be formed on the preliminary first layer P-LL1. The preliminary anti-oxidation layer P-LL3 may be formed by depositing titanium nitride by a sputtering method. The preliminary second layer P-LL2 may be formed on the preliminary anti-oxidation layer P-LL3. The preliminary second layer P-LL2 may be formed by depositing a transparent conductive oxide by a sputtering method. For example, the preliminary second layer P-LL2 may be formed of an indium tin oxide.

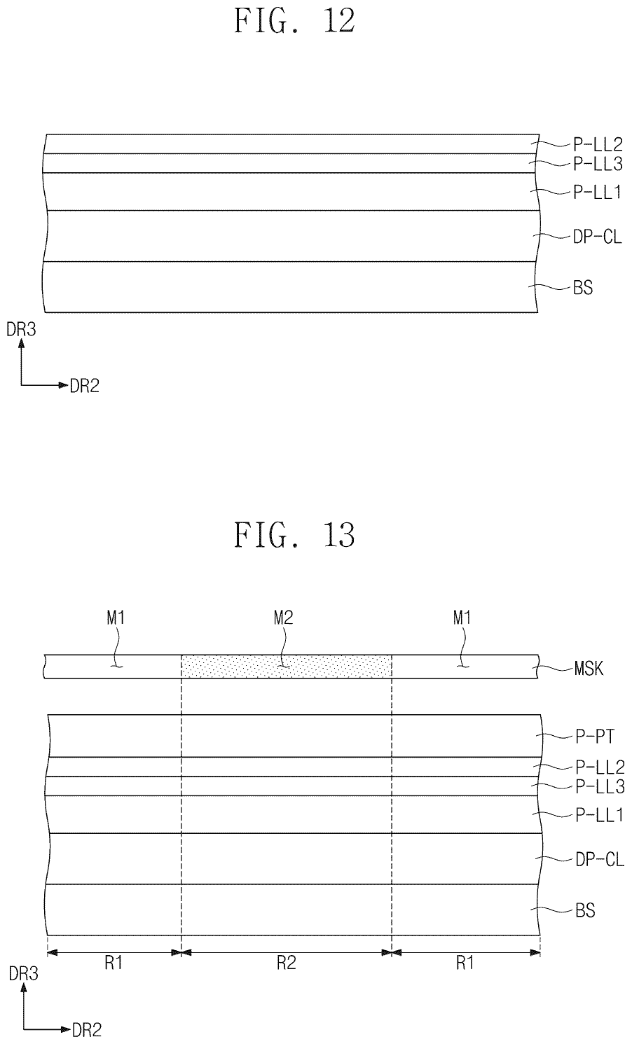

In an embodiment and referring to FIG. 13, a photosensitive film P-PT may be provided on the entire surface of the preliminary second layer P-LL2. The photosensitive film P-PT may be exposed to light through a mask MSK. The mask MSK may be composed of a first portion M1 that blocks all irradiated light and a second portion M2 that transmits some of light and blocks some of light. The preliminary first layer P-LL1, the preliminary anti-oxidation layer P-LL3, and the preliminary second layer P-LL2 may be divided into a first region R1 corresponding to the first portion M1 and a second region R2 corresponding to the second portion M2.

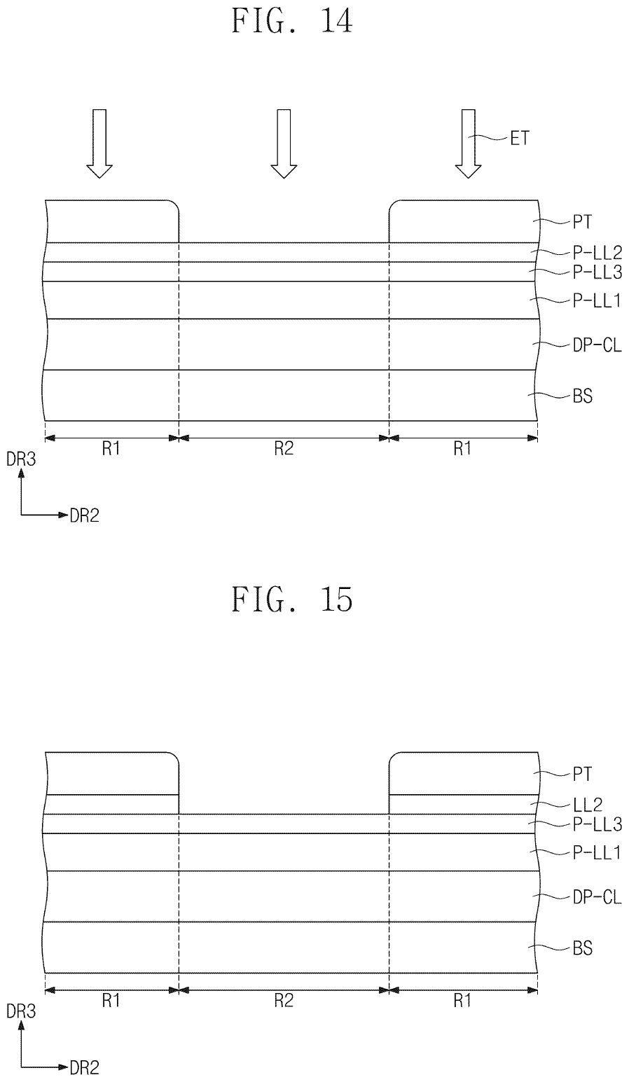

In an embodiment, after the photosensitive film P-PT exposed through the mask MSK is developed, as illustrated in FIG. 14, a photosensitive film pattern PT having a predetermined thickness may remain in the first region R1, which is blocked by the mask MSK and to which light is not provided, and the photosensitive film P-PT may be completely removed and the surface of the preliminary second layer P-LL2 may be exposed in the second region R2 to which light is provided by passing through the second portion M2 of the mask MSK. Meanwhile, FIGS. 13 and 14 exemplarily describe an embodiment in which a positive photosensitive solution is used to remove an exposed portion of the photosensitive film, but the invention is not limited thereto. A negative photosensitive solution may be used to remove an unexposed portion of the photosensitive film.

In an embodiment, the photosensitive film pattern PT may be used as a mask layer for etching the preliminary second layer P-LL2. The preliminary second layer P-LL2 may be wet-etched by an etching solution ET. The etching solution ET may be a solution that etches the preliminary second layer P-LL2 and does not etch the preliminary anti-oxidation layer P-LL3 and the preliminary first layer P-LL1. For example, the preliminary second layer P-LL2 may be formed of an indium tin oxide, and an oxalic acid-based etching solution may be provided as the etching solution ET. However, this is exemplary, and the etching solution ET is not limited thereto.

In an embodiment and referring to FIG. 15, the second layer LL2 may be formed by wet-etching the preliminary second layer P-LL2. After the second layer LL2 is formed, the surface of the preliminary anti-oxidation layer P-LL3 may be exposed in the second region R2.

In an embodiment and referring to FIGS. 16 and 17, the preliminary anti-oxidation layer P-LL3 and the preliminary first layer P-LL1 may be etched to form the anti-oxidation layer LL3 and the first layer LL1. After the anti-oxidation layer LL3 and the first layer LL1 are formed, the photosensitive film pattern PT may be removed. The photosensitive film pattern PT may be used as a mask layer for etching the preliminary anti-oxidation layer P-LL3 and the preliminary first layer P-LL1. As the photosensitive film pattern PT is disposed on the first region R1, the preliminary anti-oxidation layer P-LL3 and the preliminary first layer P-LL1 may be exposed in the second region R2.

In an embodiment, the preliminary anti-oxidation layer P-LL3 and the preliminary first layer P-LL1 may be dry-etched by providing an etching gas DG. The preliminary anti-oxidation layer P-LL3 and the preliminary first layer P-LL1 may be dry-etched and patterned into a microstructure. Fluorine gas or chlorine gas may be provided as the etching gas DG. The preliminary anti-oxidation layer P-LL3 and the preliminary first layer P-LL1 may be etched simultaneously. The preliminary anti-oxidation layer P-LL3 and the preliminary first layer P-LL1 may be collectively etched. The preliminary anti-oxidation layer P-LL3 may be formed of titanium nitride and etched in the same step as the preliminary first layer P-LL1 formed of an aluminum alloy. The method of manufacturing the display panel according to an embodiment, which includes the step of collectively etching the preliminary anti-oxidation layer P-LL3 and the preliminary first layer P-LL1 in a dry process, may exhibit excellent manufacturing efficiency and manufacturing reliability.

The display panel may be manufactured by the method of manufacturing the display panel according to an embodiment and may include a first electrode. In an embodiment, the first electrode may include a first layer formed of an aluminum alloy, a second layer formed of a transparent conductive oxide and disposed on the first layer, and an anti-oxidation layer disposed between the first layer and the second layer. The anti-oxidation layer may be formed of titanium nitride and prevent formation of an oxide film between the first layer and the second layer. In the first layer, the percentage of alloy atoms excluding aluminum atoms in the aluminum alloy may be about 0.01 at % to about 0.1 at %. Accordingly, in a high-temperature process after the forming of the first electrode in the method of manufacturing the display panel, the first layer may exhibit excellent heat resistance.

A display panel and an electronic apparatus including the display panel according to an embodiment may include a first electrode including an anti-oxidation layer disposed between a first layer and a second layer, thereby exhibiting excellent display quality.

A method of manufacturing the display panel according to an embodiment may include a step of collectively etching a preliminary first layer and a preliminary anti-oxidation layer, thereby exhibiting excellent manufacturing efficiency and manufacturing reliability.

Although the above has been described with reference to embodiments, those skilled in the art or those of ordinary skill in the art will understand that various modifications and changes can be made to the invention within the scope that does not depart from the spirit and technical field of the invention. Accordingly, it will be understood that the invention should not be limited to these embodiments. Moreover, the embodiments or parts of the embodiments may be combined in whole or in part without departing from the scope of the invention.

What is claimed is:

1. A display panel comprising:
a light-emitting element; and
a pixel defining film having a pixel opening defined therein,
wherein the light-emitting element comprises:
a first electrode exposed through the pixel opening;
a second electrode disposed on the first electrode; and
at least one functional layer disposed between the first electrode and the second electrode,
wherein the first electrode comprises:
a first layer comprising an aluminum alloy;
a second layer comprising a transparent conductive oxide; and
an anti-oxidation layer comprising titanium nitride (TiN) and disposed between the first layer and the second layer,
wherein, when the atomic percentage is about 100 at %, a percentage of alloy atoms excluding aluminum atoms in the aluminum alloy is about 0.01 at % to about 0.1 at %.

2. The display panel of claim 1, wherein the alloy atoms comprise at least one of titanium (Ti), nickel (Ni), or lanthanum (La).

3. The display panel of claim 1, wherein the first layer has a thickness of about 60 nm to about 120 nm.

4. The display panel of claim 1, wherein the second layer has a thickness of about 2 nm to about 12 nm.

5. The display panel of claim 1, wherein the transparent conductive oxide comprises an indium tin oxide (ITO).

6. The display panel of claim 1, wherein the anti-oxidation layer has a thickness of about 1 nm to about 5 nm.

7. The display panel of claim 1, wherein the first electrode has a thickness of about 63 nm to about 137 nm.

8. The display panel of claim 1, wherein the at least one functional layer comprises:
a first light-emitting layer configured to emit a first light; and
a second light-emitting layer disposed on the first light-emitting layer and configured to emit a second light, wherein the second light is different from the first light.

9. The display panel of claim 1, wherein the light-emitting element comprises a first light-emitting element, a second light-emitting element, and a third light-emitting element, each of which are spaced apart from each other in one direction, wherein the one direction is perpendicular to a thickness direction,
wherein the first light-emitting element emits red light, the second light-emitting element emits green light, and the third light-emitting element emits blue light.

10. A method for manufacturing a display panel, the method comprising:
preparing a base layer;
forming a first electrode comprising a first layer disposed on the base layer, a second layer disposed on the first layer, and an anti-oxidation layer disposed between the first layer and the second layer;
forming a functional layer on the first electrode; and
forming a second electrode on the functional layer,
wherein the forming of the first electrode comprises:
forming a preliminary first layer by providing an aluminum alloy;
forming a preliminary anti-oxidation layer on the preliminary first layer by providing titanium nitride (TiN);
forming a preliminary second layer on the preliminary anti-oxidation layer by providing a transparent conductive oxide;
forming the second layer by wet-etching the preliminary second layer; and
forming the first layer and the anti-oxidation layer by collectively etching the preliminary first layer and the preliminary anti-oxidation layer.

11. The method of claim 10, wherein, when the atomic percentage is about 100 at %, a percentage of alloy atoms excluding aluminum atoms in the aluminum alloy is about 0.01 at % to about 0.1 at %.

12. The method of claim 11, wherein the alloy atoms comprise at least one of titanium (Ti), nickel (Ni), or lanthanum (La).

13. The method of claim 10, wherein the transparent conductive oxide comprises an indium tin oxide (ITO), and wherein an oxalic acid-based etching solution is provided in the forming of the second layer.

14. The method of claim 10, wherein the preliminary first layer and the preliminary anti-oxidation layer are dry-etched.

15. The method of claim 10, wherein, in the forming of the first layer and the anti-oxidation layer, a fluorine gas or chlorine gas is provided.

16. An electronic apparatus comprising:
a display panel; and
a lens system disposed opposite to the display panel,
wherein the display panel comprises:
a light-emitting element; and
a pixel defining film having a pixel opening defined therein,
wherein the light-emitting element comprises:
a first electrode exposed through the pixel opening;
a second electrode disposed on the first electrode; and
at least one functional layer disposed between the first electrode and the second electrode,
wherein the first electrode comprises:
a first layer comprising an aluminum alloy;
a second layer comprising a transparent conductive oxide; and
an anti-oxidation layer comprising titanium nitride (TiN) and disposed between the first layer and the second layer,
wherein, when the atomic percentage is about 100 at %, a percentage of alloy atoms excluding aluminum atoms in the aluminum alloy is about 0.01 at % to about 0.1 at %.

17. The electronic apparatus of claim 16, wherein the alloy atoms comprises at least one of titanium (Ti), nickel (Ni), or lanthanum (La).

18. The electronic apparatus of claim 16, wherein the first layer has a thickness of about 60 nm to about 120 nm,
the second layer has a thickness of about 2 nm to about 12 nm, and
the anti-oxidation layer has a thickness of about 1 nm to about 5 nm.

19. The electronic apparatus of claim 16, wherein the at least one functional layer comprises:
a first light-emitting layer configured to emit a first light; and
a second light-emitting layer disposed on the first light-emitting layer and configured to emit a second light that is different from the first light.

20. The electronic apparatus of claim 16, wherein the light-emitting element comprises a first light-emitting element, a second light-emitting element, and a third light-emitting element, each of which are spaced apart from each other in one direction, wherein the one direction is perpendicular to a thickness direction, and
wherein the first light-emitting element emits red light, the second light-emitting element emits green light, and the third light-emitting element emits blue light.
